(19) United States
(12) Patent Application Publication
(10) Pub. No.: US 2017/0046102 A1
(43) Pub. Date: Feb. 16, 2017

(54) FLEXIBLE INTERFACE FOR NAND FLASH MEMORY

(71) Applicant: Marvell World Trade Ltd., St. Michael (BB)

(72) Inventors: Jinjin He, Santa Clara, CA (US); Wei Xu, Milpitas, CA (US); Young-Ta Wu, Fremont, CA (US); Ka-Ming Keung, San Jose, CA (US); Xueting Yu, San Jose, CA (US); Dongwan Zhao, Santa Clara, CA (US); Rohitkumar Makhija, San Jose, CA (US); Jie Chen, Milpitas, CA (US); Madhu Kalluri, Fremont, CA (US); Qinghua Fu, San Jose, CA (US)

(21) Appl. No.: 15/229,646

(22) Filed: Aug. 5, 2016

Related U.S. Application Data
(60) Provisional application No. 62/205,142, filed on Aug. 14, 2015.
(60) Provisional application No. 62/297,230, filed on Feb. 19, 2016.

(51) Int. Cl. G06F 3/06; G06F 13/16; G06F 9/48; G11C 16/10

(52) U.S. Cl. CPC G06F 3/0659; G11C 16/10; G06F 3/0625; G06F 3/061; G06F 3/0688; G06F 13/1689; G06F 9/4881

(57) ABSTRACT

A memory channel command interface for one or more memory channels includes, for each memory channel, programmable storage for memory commands, a single channel processor for executing the memory commands, and a task engine for communicating output of the single channel processor to a memory medium. The memory commands may be organized into jobs including operations that include tasks. The tasks may be stored as part of operations in an operation memory, or may be stored in a task memory with pointers to the tasks being stored as part of operations in the operation memory. The memory channel command interface may further include a memory medium status storage that stores a priority indication for a memory command, based on a condition other than order of arrival or receipt of the memory command, and the single channel processor controls order of execution of memory commands based on the priority indication.

### CROSS REFERENCE TO RELATED APPLICATION

This claims the benefit of copending, commonly-assigned U.S. Provisional Patent Applications Nos. 62/205,142 and 62/297,230, filed Aug. 14, 2015 and Feb. 19, 2016, respectively, each of which is hereby incorporated by reference herein in its respective entirety.

### FIELD OF USE

Implementations of the subject matter of this disclosure generally pertain to memory interfaces, and particularly to a flexible interface, which may be reconfigurable, for memory devices such as NAND Flash memory.

### BACKGROUND

The background description provided herein is for the purpose of generally presenting the context of the disclosure. Work of the inventor hereof, to the extent the work is described in this background section, as well as aspects of the description that may not otherwise qualify as prior art at the time of filing, are neither expressly nor impliedly admitted to be prior art against the present disclosure.

Different types of interfaces exist for NAND Flash memory. For example, there are interfaces based on the Open NAND Flash Interface (ONFI) standard is available from the Open NAND Flash Interface workgroup, while the Toggle Mode standard was developed by Toshiba Corporation for its Flash memory products. However, in known standards such as ONFI and Toggle Mode, the command sequences are fixed. In hardware implementations, the commands may be hard-coded. For example, each command sequence may be implemented as a Finite State Machine. Therefore, it may be complicated to change a command sequence when necessary or desired. Moreover, different NAND Flash vendors may have different custom commands, requiring custom changes whenever a command sequence is to be revised.

In addition, some known Flash memory interfaces use multiple processors for each memory channel, with attendant consequences for power consumption. Commands generally are executed in the order in which they are received, on a processor-by-processor basis, regardless of their relative importance.

### SUMMARY

In accordance with implementations of the subject matter of this disclosure, a memory channel command interface for one or more memory channels includes, for each of the one or more memory channels, programmable storage for memory commands, a single channel processor for executing the memory commands, and a task engine for communicating output of the single channel processor to a memory medium.

In such implementations, the memory commands may be organized into jobs including operations that include tasks, and the programmable storage for memory commands includes a job memory and an operation memory. The tasks may be stored as part of operations in the operation memory, or the programmable storage for memory commands may include a task memory, with tasks being stored in the task memory, and pointers (to the tasks stored in the task memory) being stored as part of operations in the operation memory.

In some implementations, the memory channel command interface further includes a memory medium status storage. The memory medium status storage may store a priority indication for a memory command, the priority indication may be based on a condition other than order of arrival or receipt of the memory command, and the single channel processor controls order of execution of memory commands based on the priority indication.

According to some implementations, a method of operating a memory channel command interface includes programming memory tasks into programmable storage in the memory channel command interface, entering a command into the memory channel command interface, and executing the command by selecting ones of the memory tasks from the programmable storage. The priority indication for each command in the plurality of commands may be based on a condition other than order of arrival or receipt of the command, and the plurality of commands may be executed in an order based on the priority indication.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 shows an example of a system including NAND Flash memory;

FIG. 2 shows a known implementation of NAND Flash interface driver;

FIG. 3 shows NAND Flash interface driver according to a first implementation of the subject matter of this disclosure;

FIG. 4 shows an example of the structure of a NAND Flash command job;

FIG. 5 shows a first example of a command phase within a NAND Flash command job;

FIG. 6 shows a second example of a command phase within a NAND Flash command job;

FIG. 7 shows a third example of a command phase within a NAND Flash command job;

FIG. 8 shows the structure of an example of a read command job;

FIG. 9 shows the command flow of the example read command job of FIG. 8;

FIG. 10 shows the processor flow of the example read command job of FIG. 8;

FIG. 11 shows the channel I/O flow of the example read command job of FIG. 8;

FIG. 12 shows an example of a format for a “command” task;

FIG. 13 shows an example of a format for an “address” task;

FIG. 14 shows an example of a format for a “wait” or “delay” task;

FIG. 15 shows an example of a format for a “data_in” task;

FIG. 16 shows an example of a format for a “data_out” task;

FIG. 17 shows an example of the format of a command job;

FIG. 18 shows an example of an operation stored in an operation memory;

FIG. 19 shows an example of the structure of a phase of the operation of FIG. 18;

FIG. 20 shows an example of the operational flow of the operation of a logical unit status memory;

FIG. 21 shows an example of bit masks used to store logical unit status in a logical unit status memory; and

FIG. 22 shows an example of look-up tables used in NAND Flash interface driver according to a second implementation of the subject matter of this disclosure.

### DETAILED DESCRIPTION

As noted above, in existing Flash memory interfaces, particularly NAND Flash memory interfaces, commands may be hard-coded. For example, each command sequence may be implemented as a Finite State Machine. This makes it complicated to change a command sequence when necessary or desired, and the situation is further complicated by different commands under different standards and from different vendors.

Moreover, known Flash memory interfaces use multiple processors for each memory channel, even though many of the processors sit unused for much of the time. Those processors consume power unnecessarily while sitting idle, increasing overall power consumption of the interface above what otherwise would be necessary.

In addition, commands generally are executed in the order in which they are received, on a processor-by-processor basis, regardless of their relative importance, even though some commands may have a higher degree of urgency, or otherwise have higher relative importance, than other commands.

In accordance with implementations of the subject matter of this disclosure, an interface driver for NAND Flash memory may be provided, in which commands can be defined or changed by the user. Because the commands can be changed, command sequences from different vendors can be accommodated, and both ONFI and Toggle Mode standards, as well as other standards, can be used.

Implementations of the subject matter of this disclosure also use one processor to perform multiple “jobs” or commands. For example, there may be one processor per channel. This reduces power consumption. A memory structure, programmable by a user, stores the available commands or “tasks” which may be invoked. That memory structure may include a look-up table which can be altered by the user.

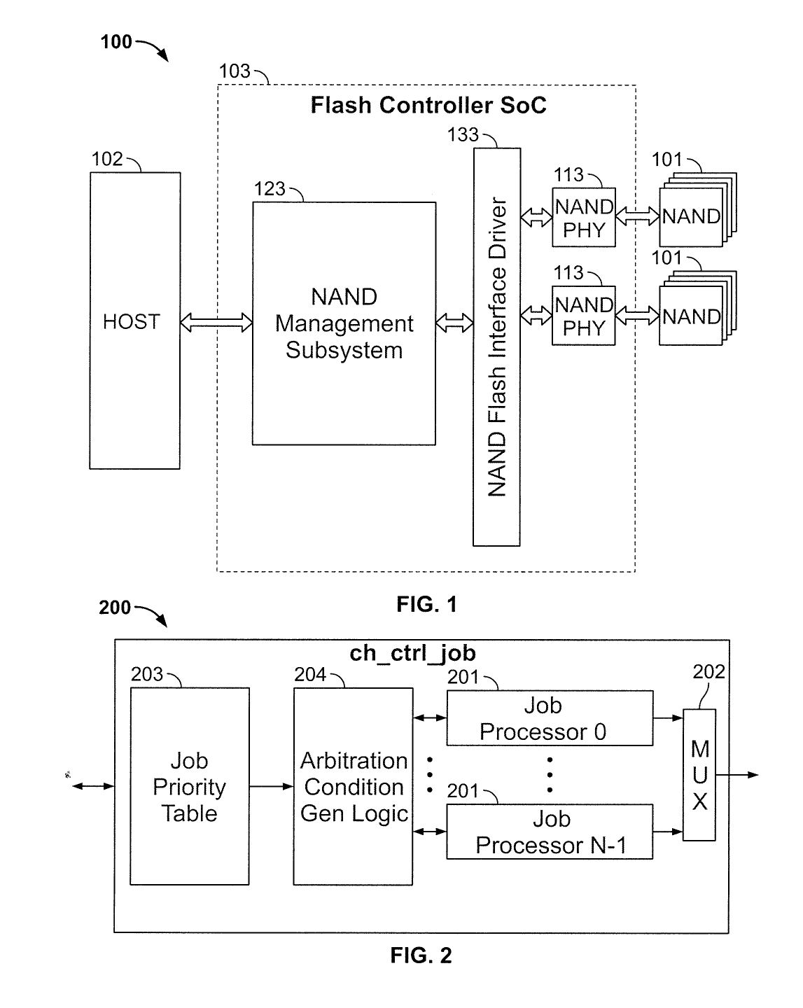

FIG. 1 shows an example of a system 100 including NAND Flash memory. One or more NAND Flash memory units 101 communicate with a host system 102 (which may be, e.g., a personal computer) via Flash controller 103. Flash controller 103, which may be implemented, e.g., as a system-on-chip, may include one or more NAND Physical Layer Interface (PHY) units 113, each of which handles the actual physical layer communication with one or more of the NAND Flash memory units 101. A NAND management subsystem 123 interfaces with host system 102, receiving and responding to memory requests from host system 102. NAND Flash interface driver 133 sits between NAND management subsystem 123 and NAND PHY units 113. Among other functions, NAND Flash interface driver 133 translates memory requests from host system 102 into more elemental commands or tasks that can be relayed to a NAND PHY unit 113 for communication to a NAND Flash memory unit 101.

As noted above, known NAND Flash interface drivers have been difficult to change once implemented. For example, a NAND Flash interface driver may be implemented as a plurality of hard-wired finite state machines (not shown) corresponding to different command sequences. In such an implementation, changing (or adding) any command sequence requires changing (or adding) the corresponding finite state machine. In order to provide for simultaneous issuance of the same command one more than one memory channel, for each command sequence there may be multiple instances of the corresponding finite state machine, each of which would have to be changed if the corresponding command sequence is to be changed.

Another known implementation of a NAND Flash interface driver 200 is shown in FIG. 2. NAND Flash interface driver 200 includes a plurality of parallel job processors 201. Each job processor 201 may be a hard-wired microprocessor. Each job processor 201 typically handles one command (which may be referred to as a “descriptor”) at a time. As each command arrives from host system 102, it is assigned a priority in job priority table 203. Generally, priority in such a system is determined by order of arrival.

Normally, any job processor 201 can work on a command for any one of the logical units (LUNs) in the NAND Flash memory units 101. Multiplexing circuitry 202 directs the output of each job processor 201 to the correct LUN. Arbitration logic 204 determines which command is processed by which job processor 201. As one example, the following arbitration rules may be applied:
1. Command descriptors are processed in the order in which they are received.
2. Different command descriptors for the same LUN are processed in order; notwithstanding Rule 1, a command descriptor for a particular LUN will be held if a different command descriptor for that LUN is still being processed, and in that case a command descriptor for a different LUN will be processed even if it were received later.
3. Program descriptors are processed in order—i.e., program data in order (even if, under Rule 2, command descriptors are processed out of order).
4. Read descriptors are processed so that read data are transferred in order (even if, under Rule 2, command descriptors are processed out of order).

In a NAND Flash interface such as NAND Flash interface driver 200, utilization of job processors 201 may be low. For example, if multiple command descriptors for the same LUN are assigned to different ones of job processors 201, only one of those job processors 201 can be active at any one time. Each other one of job processors 201 has to wait until all earlier command descriptors have been executed by other ones of job processors 201. Many job processors 201 remain inactive most of the time, particularly during status polling.

In addition, complicated arbitration logic may be required for such an arrangement. Each of job processors 201 may need to check the state of each other one of job processors 201 to determine its own next action. The complexity of the arbitration process increases as the square of the number N of job processors 201. Moreover, it is difficult to close timing for this arrangement.

Finally, whether a command descriptor is executed by a job processor 201, or as a state machine (not shown), in known systems the commands are hard-coded. Therefore, flexibility to support different commands is limited.

In accordance with implementations of the subject matter of this disclosure, one processor per channel executes configurable NAND Flash commands. The processor may be command-unaware—i.e., there is nothing about the processor that is constructed for a particular command. This increases the flexibility of the processor to execute any command configured by a user.

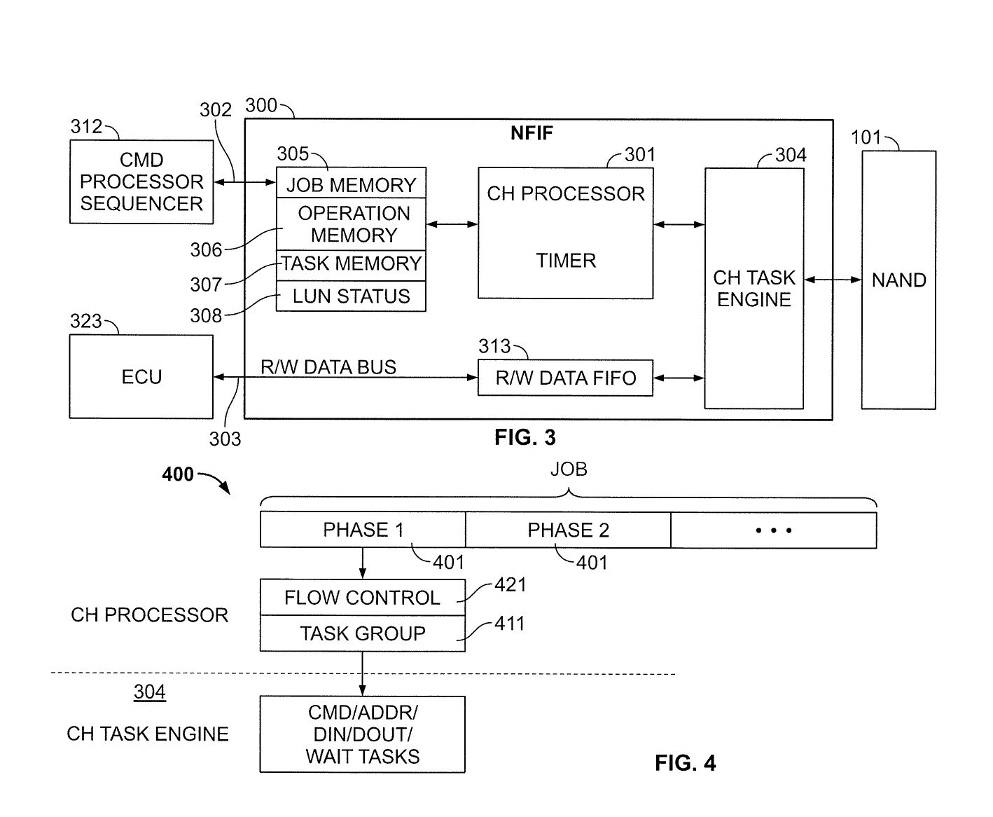

One example of a NAND Flash interface (NFIF) driver 300 according to an implementation of the subject matter of this disclosure is shown in FIG. 3. The plurality of job processors 201 is replaced by a single per-channel processor 301. Channel processor 301 may be a programmable microprocessor for increased flexibility. Commands are input at 302 (e.g., from a command processor 312), while data are input or output on read/write data bus 303. A channel task engine 304 combines the output of channel processor 301 with data from read/write data first-in/first-out circuit (FIFO) 313, which connects to read/write data bus 303, which in turn connects to error correction unit (ECU) 323. Channel task engine 304 communicates—e.g., through NAND PHY units 113—with NAND Flash memory units 101.

The execution by channel processor 301 of commands input at 302 is controlled in accordance with the contents of job memory 305, operation memory 306, task memory 307, and LUN status memory 308.

As shown in FIG. 4, a command “job” 400 includes one or more phases 401. Each phase 401 includes a task group 411, and flow control 421 which controls how many times task group 411 is executed (each task group 411 could be executed more than once). Each task group 411 includes the actual command (CMD), address (ADDR), data-in (DIN), data-out (DOUT) and WAIT tasks that are sent to the NAND Flash memory units 101. As shown in this example, the execution of flow control 421 to perform a task group 411 is performed in channel processor 301, while the actual tasks in task group 411 are executed in channel task engine 304.

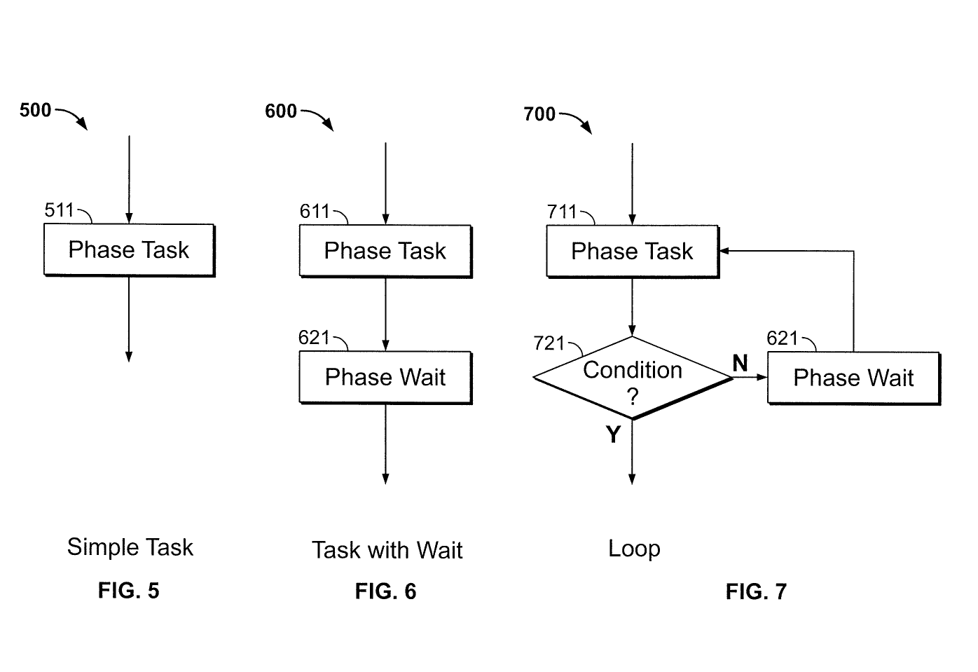

FIGS. 5-7 show different examples of flow control 421. For a simple phase 500 (FIG. 5), the task group 511 (“phase task”) of that phase is performed just once according to the associated flow control 421 (not shown in FIG. 5). For a somewhat more complicated phase 600 (FIG. 6), the phase task 611 is again performed just once according to the associated flow control 421, but flow control 421 also includes a wait command (“phase wait”) 621 following phase task 611. In a loop-type phase 700 (FIG. 7), the phase task 711 may be performed multiple times, according to a condition 721 in the associated flow control 421. In addition, flow control 421 may also include a phase wait 621.

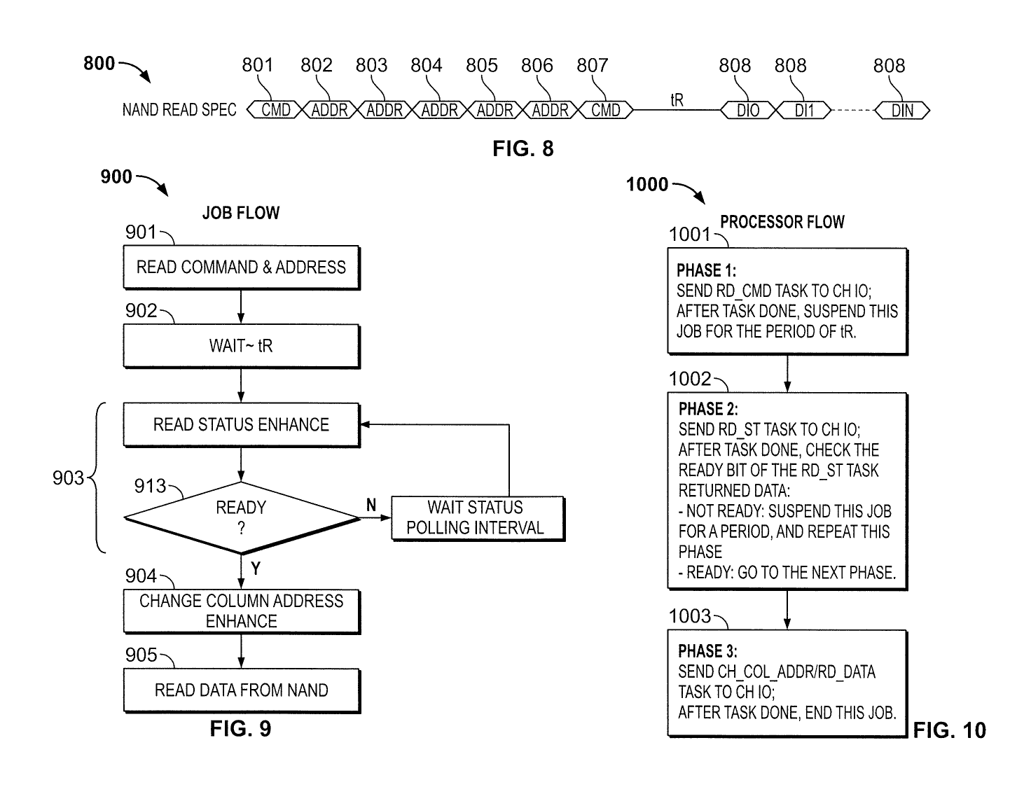

FIGS. 8-11 show an example of a read command job 800. As seen in FIG. 8, job 800 includes a command byte 801, five address bytes 802-806 and another command byte 807. After a waiting, or resting, time t_{R}, one command byte 808 and three address bytes 809-811 are sent out to check the status of the NAND Flash memory. The status checking may occur more than once until status byte 812 indicates that the data are ready in the NAND Flash memory. When the data are ready, a command byte 813, five address bytes 814-818 and another command byte 819 are issued to the NAND Flash memory to start the data transfer and n data bytes 820 are returned. The corresponding flows at the job level, the processor level and the channel I/O level are shown in FIGS. 9-11, respectively.

Job flow 900 (FIG. 9) starts with the read command and address 901, followed by wait time t_{R} 902. During this wait time t_{R} 902, the buffer is loaded in NAND Flash memory units 101 with the requested data. Loop 903 checks continually until loading is complete, as signified by a “YES” result from test 913. Once loading is complete, an output command is issued at 904 (“change column address enhance”) and the data are read out at 905.

At the processor level (FIG. 10), in a first phase 1001 of processor flow 1000, the read command is sent by processor 301 to the channel task engine 304 and the job is then suspended, as far as processor 301 is concerned, for wait time t_{R} 902. First phase 1001 corresponds to 901 and 902 in job flow 900.

In a second phase 1002 (corresponding to loop 903), a read status task is sent by processor 301 to the channel task engine 304 and the ready bit of the returned task is checked. If the ready bit signifies “not ready,” the job is suspended for a polling interval and the read status task is then repeated. If the ready bit signifies “ready,” the phase is complete and processor flow 1000 moves on to a third phase 1003.

In third phase 1003 (corresponding to 904 and 905), change column address and read data tasks are sent by processor 301 to the channel task engine 304 and the job is completed.

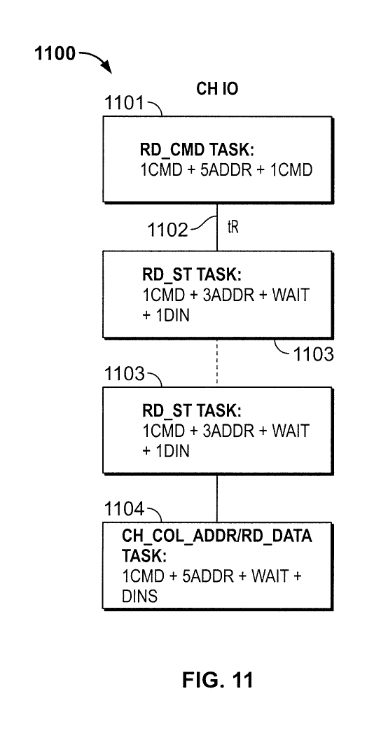

At the channel level, the channel I/O flow 1100 (FIG. 11), starts with a read command task 1101 (corresponding to 901 and 902, and to phase 1001) including a command byte, five address bytes and another command byte (cf. FIG. 8), followed by wait time t_{R} 1102. This is followed by as many read status tasks 1103 as are necessary (corresponding to loop 903 and phase 1002), where each read status task may include one command byte, three address bytes, one wait byte and one data_in byte. Flow 1100 ends with change column address and read data tasks 1104 (corresponding to 904 and 905 and phase 1003), which may include one command byte, five address bytes, one command byte, one wait byte and as many data_in bytes as are necessary.

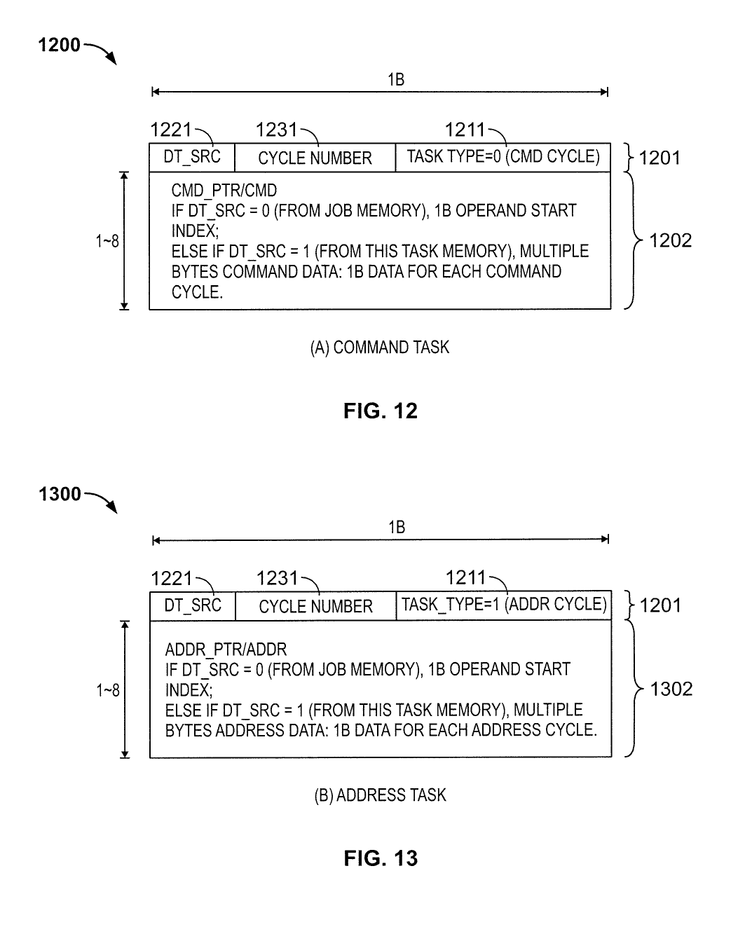

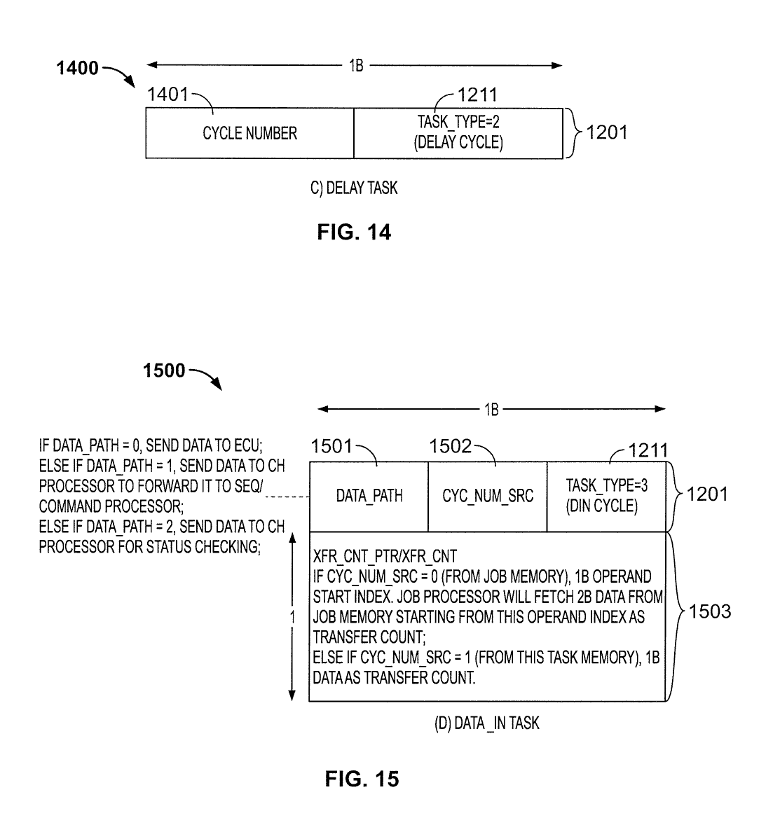

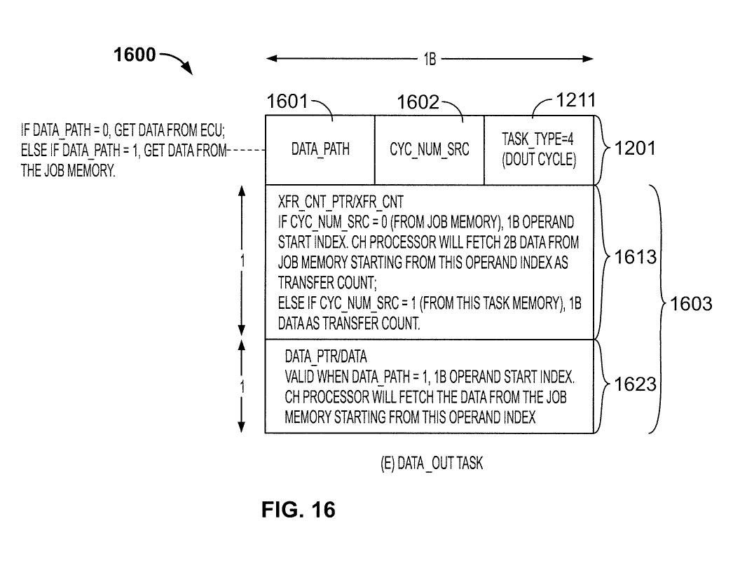

As noted above, in accordance with implementations of the subject matter of this disclosure, efficient task definitions can be assembled into task phases and jobs. FIGS. 12-16 show examples of task formats. FIG. 12 shows a format for a command task 1200, which may be designated task_type 0. FIG. 13 shows a format for an address task 1300, which may be designated task_type 1. FIG. 14 shows a format for a wait or delay task 1400, which may be designated task_type 2. FIG. 15 shows a format for a data_in task 1500, which may be designated task_type 3. FIG. 16 shows a format for a data_out task 1600, which may be designated task_type 4. In accordance with the ONFI specification, for example, a command task may occupy 64 bytes and include up to 32 commands, an address task may occupy 14 bytes, a data_in task may occupy 18 byte, a data_out task may occupy 16 bytes and a WAIT task may occupy 4 bytes for a total of 116 bytes. Therefore, task memory 307 may be 128 bytes.

In the example shown in FIGS. 12-16, each task format except the wait or delay task 1400 (task_type 2) includes one header byte 1201 and at least one additional byte. In each format, the second half 1211 of the header byte 1201—i.e., 4 bits—is reserved for the task type. Although only 3 bits are necessary to accommodate five task types, additional task types may be provided.

In task formats 1200 (command) and 1300 (address), the first bit 1221 of header byte 1201 is a data_source bit which signifies whether the task data are found in job memory 305 or task memory 307. The following three bits represent the cycle number 1231, which signifies how many additional bytes 1202/1302 are included in the task (and how many clock cycles are required for task execution); with three bits, a total of eight additional bytes may be provided.

In task format 1400 (wait or delay), the first half 1401 (four bits) of the header byte 1201 represents the number of clock cycles in the delay task—i.e., the length of the delay as measured in clock cycles. With four bits, up to 16 cycles of delay are possible.

In task format 1500 (data_in), the first two bits 1501 represent the data path. In the example shown, there are three choices—the data are sent to ECU 323, or to channel processor 301 for forwarding to command processor 312, or to channel processor 301 for status checking, but up to four choices can be accommodated with two bits. Similarly, the next two bits 1502 represent the cycle number source—i.e., the source of data for the current cycle, which can come from job memory 305 or from the current task memory 307, although up to four choices can be accommodated with two bits. As shown, task 1500 is expected to include only one byte 1503 in addition to the header byte 1201.

In task format 1600 (data_out), the first two bits 1601 represent the data path. In the example shown, there are only two choices—the data are obtained either from ECU 323 or from job memory 305, but up to four choices can be accommodated with two bits. As shown, task 1600 is expected to include one or two bytes 1603 in addition to the header byte 1201, as a function of the data path selected by bits 1601. The contents 1613, 1623 of that byte or bytes differ depending on the data path selected by bits 1601. If bits 1601=‘0’, the selected data path includes ECU 323, and the two bits 1602 determine whether the data come from job memory 305 or task memory 307. There is only one byte 1603 having contents 1613, which determines the start index and/or transfer count. If bits 1601=‘1’, the selected data path includes job memory 305, and there are two bytes 1603, one of which has content 1613, and the other of which has content 1623.

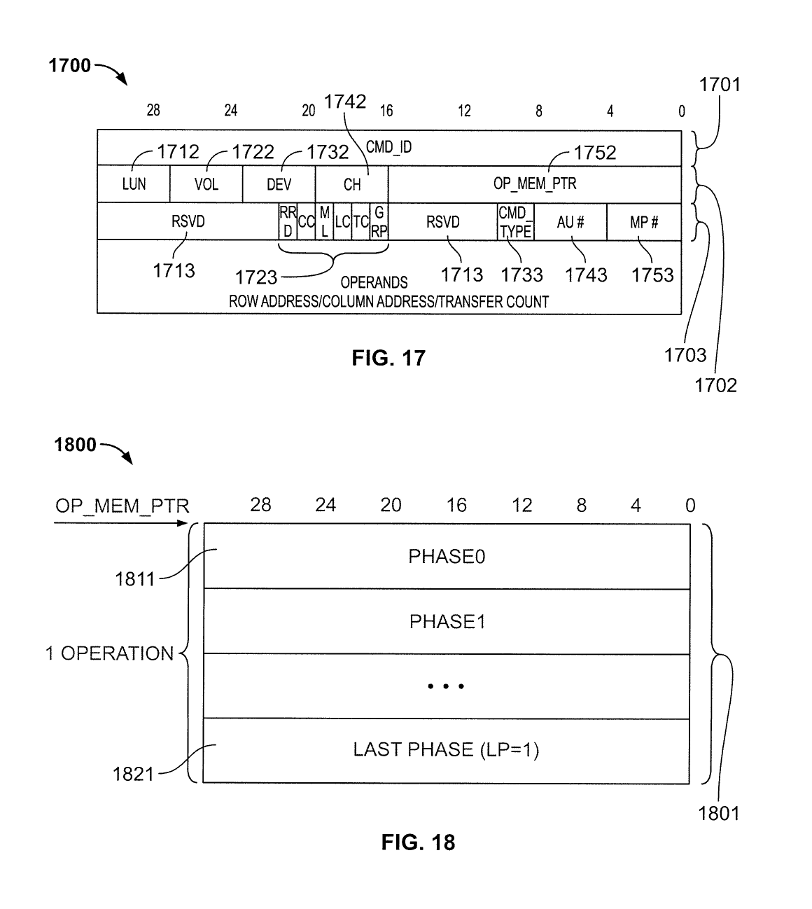

As noted above, tasks are grouped into phases which are grouped into jobs (also referred to as “operations”). Command processor 312 deposits jobs into job memory 305. An example format 1700 of a job in job memory 305 is shown in FIG. 17 and is 32 bits wide. First line 1701 contains the command ID, which may be up to 32 bits wide. The second line 1702 includes address information including logical unit (LUN) number 1712, volume (VOL) number 1722, device (DEV) number 1732 and channel (CH) number 1742, all of which are shown as being 4 bits wide, as well a pointer 1752 to the operations that make up the job. The third line 1703 includes, in addition to two reserved fields 1713, a number of flow control bits (RRD, CC, ML, LC, TC and GRP) 1723, a command type 1733, and further address information including an allocation unit (AU) number 1743 and a multi-plane (MP) number 1753 (in case multiple pages are involved; for a single-plane operation involving only one page, MP=0). The remaining line(s) 1704 include the operands for the job.

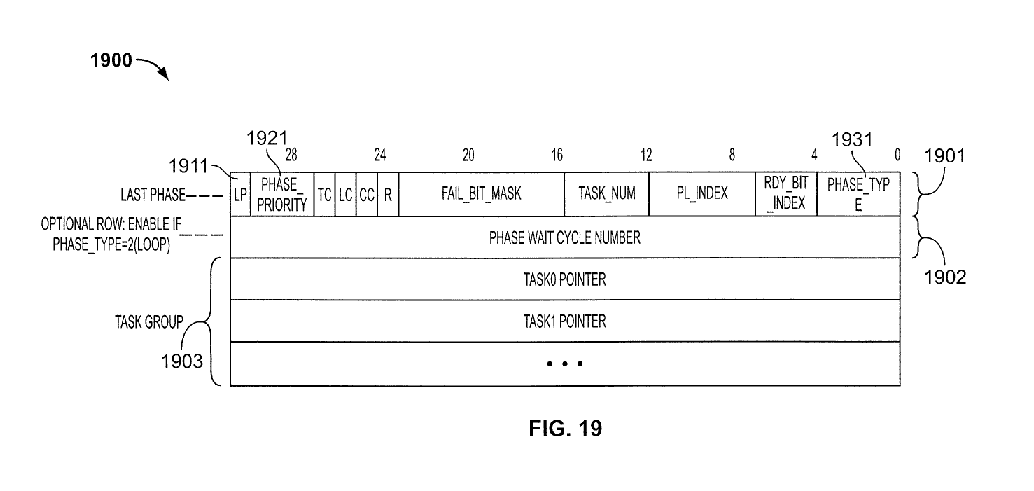

The operations that make up the job may be stored in operation memory 306, and that is where pointer 1752 may point. FIG. 18 shows one operation 1800 stored in operation memory 306 and pointed to by pointer 1752. Operation 1800 includes a plurality of phases 1801, starting with Phase 0 (1811) and ending with a last phase 1821. Because the number of phases is not fixed, the last phase 1821 is identified by the value in a last-phase field (LP) (see FIG. 19).

FIG. 19 shows an example of the structure 1900 of a phase 1801. In this example, phase 1900 is 32 bits wide. The first line 1901 of phase 1900 includes, among other fields, a last phase (LP) field 1911 as discussed above. The value in LP field 1911 signals whether or not this phase 1900 is a “last phase” in its job, as discussed above. For example, a ‘0’ could indicate that this is not the last phase, while a ‘1’ could indicate that this is the last phase, or vice-versa.

Line 1901 of phase 1900 includes, among other fields, a phase priority field 1921 which is discussed further below, and a phase type field 1931. The value in phase type field 1931 may correlate (e.g., values 0, 1 and 2) to the three types of phases 500, 600, 700 shown in FIGS. 5-7. In that connection, line 1902 of phase 1900 is an optional line for the case of phase type=1 or phase type=2, which indicates at task with wait phase 600 or a loop phase 700, respectively, and contains a phase wait cycle number.

The remaining lines of phase 1900 contain information regarding the tasks in the task group 1903 of phase 1900. As shown in FIG. 19, each of the lines in task group 1903 contains a pointer to a task in task memory 307. However, in many implementations the task formats themselves may be small enough to fit, instead of a pointer, into one line (which is four bytes long) of task group 1903. In such implementations, task memory 307 may be omitted. For example, as shown in FIGS. 12-16, some task formats may be only one or two bytes long, and while other task formats may be up to eight bytes long, they can be shorter, and any task that is up to four bytes long will fit into a line of phase 1900.

The contents of operation memory 306 and, where provided, task memory 307, can be programmed to accommodate the command and signal structures of NAND Flash products from different vendors. Moreover, operation memory 306 and, where provided, task memory 307 may be user-programmable to accommodate custom user tasks and commands.

LUN status memory 308 may be used to provide one of the following status indications for each LUN in NAND Flash memory units 101:

IDLE: no job on this LUN.

PENDING: job is pending.

PRE-ACTIVE: next phase task group pre-fetched.

ACTIVE: phase is selected to use Task Engine.

WAIT: phase wait. The job is suspended during WAIT. LUN status memory 308 also may include information regarding chain and wait time status, as is known.

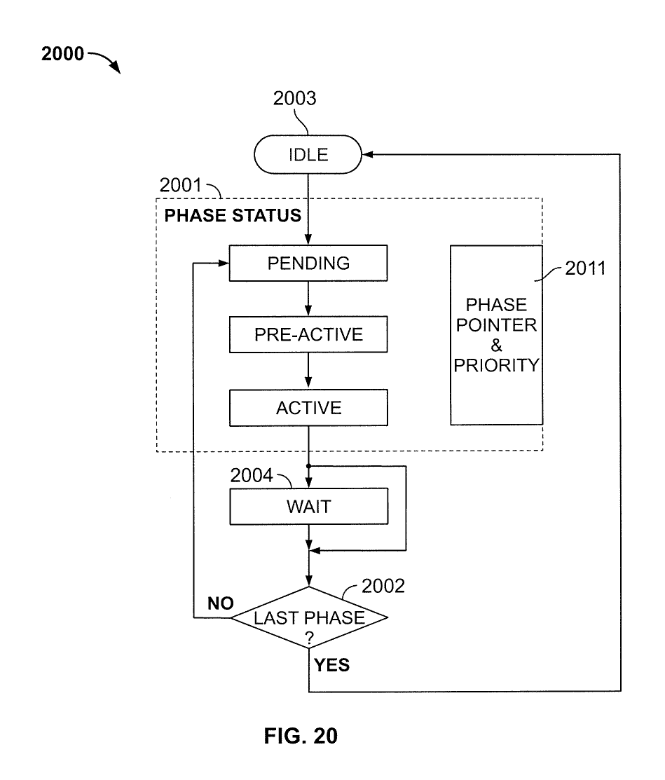

The operational flow 2000 of the operation of LUN status memory 308 is diagrammed in FIG. 20. As shown in FIG. 20, the phase status (see previous paragraph) for each LUN is indicated in phase status 2001. Phase status 2001 also stores at 2011 a phase pointer for the current phase status for the LUN under consideration, as well as a priority level for the current phase status, which priority level is based on something other than order of arrival or receipt. Priority levels can be set by the user. In addition, a phase may have a higher priority if is part of a chain of phases or operations that should not be interrupted. Processor 301 can use the priority level to perform a phase out of the order in which it was received, unlike previously known NAND Flash interface drivers.

Operational flow 2000 is best understood starting at the end, at test 2002 where it is determined whether the current phase is the last phase in its job. If, at test 2002, the current phase is the last phase in its job, flow returns to 2003 where the LUN status is indicated as IDLE until a new job is assigned to the LUN under consideration. If, at test 2002, the current phase is not the last phase in its job, flow returns to 2001 where the status of the next phase is either PENDING, PRE-ACTIVE, or ACTIVE, and eventually executes. After that phase executes, flow proceeds to test 2002 to determine, again, whether the current phase is the last phase in its job, unless the phase includes a phase wait, in which case flow proceeds to WAIT status 2004 until the wait time elapses and then flow proceeds to test 2002.

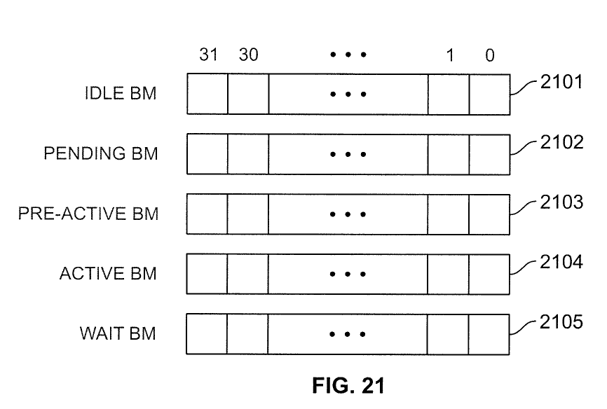

The storage format for the various status indicators in LUN status memory 308 may be in the form of a bit mask for each status type. For example, as shown in FIG. 21, each status bit mask is 32 bits wide, with each bit representing the index of a particular LUN. As shown, there is a separate bit mask 2101-2105 for IDLE, PENDING, PRE-ACTIVE, ACTIVE and WAIT. The status of each LUN may be indicated by a ‘1’ in the index location of that LUN in the bit mask for the appropriate status, with a ‘0’ appearing in that location in all other bit masks. Alternatively, the status of each LUN may be indicated by a ‘0’ in the index location of that LUN in the bit mask for the appropriate status, with a ‘1’ appearing in that location in all other bit masks.

Other information that may be stored in LUN status memory 308 can include, for each LUN, a wait-time stamp (as discussed above), a pointer to the next phase for that LUN (in addition to the aforementioned pointer to the current phase), a pointer to the next task for that LUN, and an identification of the job or command that the current phase corresponds to.

In another implementation of the subject matter of this disclosure, instead of providing operation memory 306 (and optional task memory 307) with predefined operations and tasks, a set of look-up tables may be provided containing sequences that a user can select to construct various operations and tasks.

At a basic level, a NAND Flash interface is a set of signals (read-enable, write-enable, clear, etc.). Thus, a NAND Flash transaction is a series of toggles of one or more of those signals. A collection of values for each of the interface signals and a hold time for each signal value on the NAND Flash command bus may be defined as a signal frame. In turn, a NAND Flash task may be defined as a sequence of signal frames, and NAND Flash operation may be defined as a sequence of tasks.

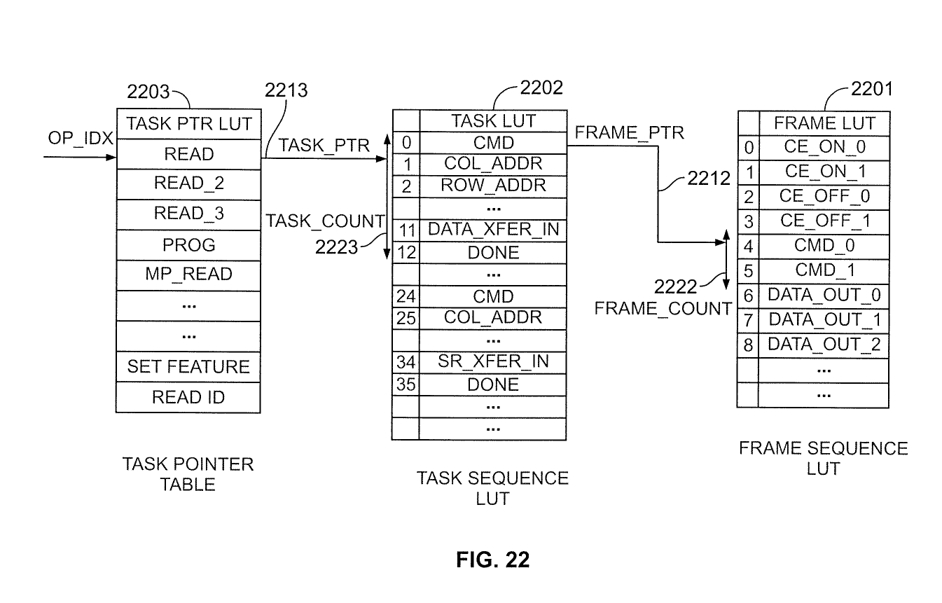

Therefore, in this implementation, the operation memory 306 and task memory 307 can be replaced with the look-up tables (LUTs) shown in FIG. 22. Each entry in Frame Sequence LUT 2201 represents an interface signal state and hold time. Each entry in Task Sequence LUT 2202 represents a command that can be part of a task sequence, and includes a pointer 2212 to an entry in Frame Sequence LUT 2201, and a counter 2222 to indicate a number of entries from the pointed-to entry that together make up the command represented by the entry in the Task Sequence LUT 2202. Alternatively, if the entries in Frame Sequence LUT 2201 that make up the command represented by the entry in Task Sequence LUT 2202 are not contiguous in Frame Sequence LUT 2201, then each entry in Task Sequence LUT 2202 can include a set of pointers (not shown) to the entries in Frame Sequence LUT 2201 that make up the command represented by the entry in Task Sequence LUT 2202.

In turn, each entry in Task Pointer LUT 2203 represents a memory operation which is made up of a sequence of tasks, and includes a pointer 2213 to an entry in Task Sequence LUT 2202, and a counter 2223 to indicate a number of entries from the pointed-to entry that together make up the memory operation represented by the entry in the Task Pointer LUT 2203. Alternatively, if the entries in Task Sequence LUT 2202 that make up the memory operation represented by the entry in Task Pointer LUT 2203 are not contiguous in Task Sequence LUT 2202, then each entry in Task Pointer LUT 2203 can include a set of pointers (not shown) to the entries in Task Sequence LUT 2202 that make up the memory operation represented by the entry in Task Pointer LUT 2203.

Look-up tables 2201, 2202, 2203 may be programmable. Therefore, the various signal sequences and command sequences can be altered to accommodate the command and signal structures of NAND Flash products from different vendors. Moreover, look-up tables 2201, 2202, 2203 may be user-programmable to accommodate custom user tasks and commands.

Thus it seen that implementations of a NAND Flash interface that is more flexible—to accommodate command and signal structures of NAND Flash products from different vendors, as well as custom user tasks and commands, have been provided. In addition, the disclosed NAND Flash interface is more efficient because there are fewer processors that sit idle most of the time, and the processors can execute tasks based on their priority rather than the order in which they are received.

Further aspects of the present invention relate to one or more of the following clauses:

Clause 1: A memory channel command interface for one or more memory channels, the memory channel command interface comprising, for each of the one or more memory channels:

programmable storage for memory commands;

a single channel processor for executing the memory commands; and

a task engine for communicating output of the single channel processor to a memory medium.

Clause 2: The memory channel command interface of clause 1, wherein the memory medium is NAND Flash memory.

Clause 3: The memory channel command interface of clause 1, wherein:

memory commands are organized into jobs including operations that include tasks; and

the programmable storage for memory commands includes a job memory and an operation memory.

Clause 4: The memory channel command interface of clause 3, wherein tasks are stored as part of operations in the operation memory.

Clause 5: The memory channel command interface of clause 3, wherein:

the programmable storage for memory commands includes a task memory;

tasks are stored in the task memory; and

pointers to the tasks stored in the task memory are stored as part of operations in the operation memory.

Clause 6: The memory channel command interface of clause 1, wherein the programmable storage for memory commands comprises at least one look-up table.

Clause 7: The memory channel command interface of clause 6, wherein:

memory commands are organized into jobs including operations that include tasks; and

the tasks are stored in a first one of the at least one look-up table.

Clause 8: The memory channel command interface of clause 7, wherein:

a job includes a sequence of the tasks;

pointers to sequences of the tasks are stored in a second one of the at least one look-up table;

the job selects one of the pointers to one of the sequences of tasks from the second one of the at least one look-up table; and

the one of the pointers selects the one of the sequences of tasks from the first one of the at least one look-up table.

Clause 9: The memory channel command interface of clause 8, wherein:

control signal sequences for the memory medium are stored in a third one of the at least one look-up table;

each task in the one of the sequence of tasks selects a control signal sequence from the third one of the at least one look-up table.

Clause 10: The memory channel command interface of clause 1, further comprising a memory medium status storage.

Clause 11: The memory channel command interface of clause 10, wherein:

the memory medium status storage stores a priority indication for a memory command;

the priority indication is based on a condition other than order of arrival or receipt of the memory command; and

the single channel processor controls order of execution of memory commands based on the priority indication.

Clause 12: The memory channel command interface of clause 11, wherein:

the memory medium status storage stores separate priority indications for each one of the memory commands; and

the single channel processor controls the order of execution of the memory commands based on the separate priority indications.

Clause 13: A method of operating a memory channel command interface, the method comprising:

programming memory tasks into programmable storage in the memory channel command interface;

entering a command into the memory channel command interface; and

executing the command by selecting ones of the memory tasks from the programmable storage.

Clause 14: The method of clause 13, wherein:

the entering a command comprises entering a plurality of commands; and

the method further comprises assigning a priority indication to each command in the plurality of commands based on a condition other than order of arrival or receipt of the command; and

the executing comprises executing the plurality of commands in an order based on the priority indication.

Clause 15: The method of clause 13, wherein the programming memory tasks into the programmable storage in the memory channel command interface comprises accepting programming of memory tasks by a user of the memory channel command interface.

Clause 16: The method of clause 15 wherein accepting programming of memory tasks by a user of the memory channel command interface comprises accepting programming of at least one look-up table.

Clause 17: The method of clause 13, wherein:

the entering the command comprises breaking the command into operations and breaking the operations into the ones of the memory tasks; and

the executing the command by selecting ones of the memory tasks from the programmable storage comprises executing the ones of the memory tasks into which the operations are broken during the entering.

Clause 18: The method of clause 13 wherein:

the programming memory tasks into programmable storage in the memory channel command interface comprises:

breaking each of the memory tasks into a respective sequence of memory interface signals, and

storing each respective sequence of memory interface signals in a first look-up table; and

the executing the command by selecting ones of the memory tasks from the programmable storage comprises looking up the respective sequences of memory interface signals in the first look-up table.

Clause 19: The method of clause 18, wherein:

the programming memory tasks into programmable storage in the memory channel command interface further comprises storing, in a second look-up table, a task pointer from each respective memory task to one of the respective sequences of memory interface signals in the first look-up table; and

the looking up the respective sequences of memory interface signals in the first look-up table comprises looking up each respective task in the second look-up table to find the task pointer to the respective sequence of memory interface signals in the first look-up table.

Clause 20: The method of clause 19, further comprising:

storing in a third look-up table a respective command pointer for each respective command to a respective sequence of task pointers in the second look-up table; wherein:

the looking up the respective sequences of memory interface signals in the first look-up table further comprises, on the entering a command into the memory channel command interface, looking up the command in the third look-up table to find the respective command pointer for each respective sequence of task pointers in the second look-up table.

It will be understood that the foregoing is only illustrative of the principles of the invention, and that the invention can be practiced by other than the described embodiments, which are presented for purposes of illustration and not of limitation, and the present invention is limited only by the claims which follow.

What is claimed is:

1. A memory channel command interface for one or more memory channels, the memory channel command interface comprising, for each of the one or more memory channels:
programmable storage for memory commands;
a single channel processor for executing the memory commands; and
a task engine for communicating output of the single channel processor to a memory medium.

2. The memory channel command interface of claim 1, wherein the memory medium is NAND Flash memory.

3. The memory channel command interface of claim 1, wherein:
memory commands are organized into jobs including operations that include tasks; and
the programmable storage for memory commands includes a job memory and an operation memory.

4. The memory channel command interface of claim 3, wherein tasks are stored as part of operations in the operation memory.

5. The memory channel command interface of claim 3, wherein:
the programmable storage for memory commands includes a task memory;
tasks are stored in the task memory; and
pointers to the tasks stored in the task memory are stored as part of operations in the operation memory.

6. The memory channel command interface of claim 1, wherein the programmable storage for memory commands comprises at least one look-up table.

7. The memory channel command interface of claim 6, wherein:
memory commands are organized into jobs including operations that include tasks; and
the tasks are stored in a first one of the at least one look-up table.

8. The memory channel command interface of claim 7, wherein:
a job includes a sequence of the tasks;
pointers to sequences of the tasks are stored in a second one of the at least one look-up table;
the job selects one of the pointers to one of the sequences of tasks from the second one of the at least one look-up table; and
the one of the pointers selects the one of the sequences of tasks from the first one of the at least one look-up table.

9. The memory channel command interface of claim 8, wherein:
control signal sequences for the memory medium are stored in a third one of the at least one look-up table;
each task in the one of the sequence of tasks selects a control signal sequence from the third one of the at least one look-up table.

10. The memory channel command interface of claim 1, further comprising a memory medium status storage.

11. The memory channel command interface of claim 10, wherein:
the memory medium status storage stores a priority indication for a memory command;
the priority indication is based on a condition other than order of arrival or receipt of the memory command; and
the single channel processor controls order of execution of memory commands based on the priority indication.

12. The memory channel command interface of claim 11, wherein:
the memory medium status storage stores separate priority indications for each one of the memory commands; and
the single channel processor controls the order of execution of the memory commands based on the separate priority indications.

13. A method of operating a memory channel command interface, the method comprising:
programming memory tasks into programmable storage in the memory channel command interface;
entering a command into the memory channel command interface; and
executing the command by selecting ones of the memory tasks from the programmable storage.

14. The method of claim 13, wherein:
the entering a command comprises entering a plurality of commands; and
the method further comprises assigning a priority indication to each command in the plurality of commands based on a condition other than order of arrival or receipt of the command; and
the executing comprises executing the plurality of commands in an order based on the priority indication.

15. The method of claim 13, wherein the programming memory tasks into the programmable storage in the memory channel command interface comprises accepting programming of memory tasks by a user of the memory channel command interface.

16. The method of claim 15 wherein accepting programming of memory tasks by a user of the memory channel command interface comprises accepting programming of at least one look-up table.

17. The method of claim 13, wherein:
the entering the command comprises breaking the command into operations and breaking the operations into the ones of the memory tasks; and
the executing the command by selecting ones of the memory tasks from the programmable storage comprises executing the ones of the memory tasks into which the operations are broken during the entering.

18. The method of claim 13 wherein:
the programming memory tasks into programmable storage in the memory channel command interface comprises:
breaking each of the memory tasks into a respective sequence of memory interface signals, and
storing each respective sequence of memory interface signals in a first look-up table; and
the executing the command by selecting ones of the memory tasks from the programmable storage comprises looking up the respective sequences of memory interface signals in the first look-up table.

19. The method of claim 18, wherein:
the programming memory tasks into programmable storage in the memory channel command interface further comprises storing, in a second look-up table, a task pointer from each respective memory task to one of the respective sequences of memory interface signals in the first look-up table; and
the looking up the respective sequences of memory interface signals in the first look-up table comprises looking up each respective task in the second look-up table to find the task pointer to the respective sequence of memory interface signals in the first look-up table.

20. The method of claim 19, further comprising:
storing in a third look-up table a respective command pointer for each respective command to a respective sequence of task pointers in the second look-up table; wherein:
the looking up the respective sequences of memory interface signals in the first look-up table further comprises, on the entering a command into the memory channel command interface, looking up the command in the third look-up table to find the respective command pointer for each respective sequence of task pointers in the second look-up table.
